(19) United States
(12) Patent Application Publication
(10) Pub. No.: US 2024/0071900 A1
(43) Pub. Date: Feb. 29, 2024

(54) SEMICONDUCTOR DEVICE

(71) Applicant: FUJI ELECTRIC CO., LTD., Kawasaki-shi (JP)

(72) Inventor: Katsumi TANIGUCHI, Matsumoto-city (JP)

(73) Assignee: FUJI ELECTRIC CO., LTD., Kawasaki-shi (JP)

(21) Appl. No.: 18/342,873

(22) Filed: Jun. 28, 2023

(30) Foreign Application Priority Data
Aug. 26, 2022 (JP) 2022-134907

(51) Int. Cl. H01L 23/498; H01L 23/00; H01L 23/31

(52) U.S. Cl. CPC H01L 23/49894; H01L 23/3107; H01L 23/49811; H01L 23/49822; H01L 23/49838; H01L 24/32; H01L 24/48; H01L 24/73; H01L 2224/32225; H01L 2224/48225; H01L 2224/73265; H01L 2924/14252; H01L 2924/1517; H01L 2924/1579

(57) ABSTRACT

A semiconductor device includes: a resin insulated substrate including a first rein insulating layer, a conductor base provided on one of main surfaces of the first resin insulating layer, and a conductor foil provided on another main surface of the first resin insulating layer; a power semiconductor element bonded to the conductor foil; a case surrounding an outer circumference of the resin insulated substrate; a sealing resin provided inside the case to seal the power semiconductor element; and a second resin insulating layer provided between the first resin insulating layer and the sealing resin and having a lower water-absorption rate than the sealing resin.

### CROSS-REFERENCE TO RELATED APPLICATION

This application claims benefit of priority under 35 USC 119 based on Japanese Patent Application No. 2022-134907 filed on Aug. 26, 2022, the entire contents of which are incorporated by reference herein.

### BACKGROUND OF THE INVENTION

### 1. Field of the Invention

The present invention relates to a semiconductor device (a power semiconductor module) equipped with power semiconductor elements.

### 2. Description of the Related Art

The demand for developing battery-powered vehicles such as electric vehicles and electric rail vehicles has grown rapidly because of worldwide trends toward decarbonization. Such a battery-powered vehicle needs to exhibit efficient control of a motor by a power conversion device such as an inverter or a converter, which is typically equipped with a power semiconductor module to execute the control. A power semiconductor module converts DC power to AC power or converts AC power to DC power. The power semiconductor module is equipped with a plurality of power semiconductor elements such as an insulated gate bipolar transistor (IGBT), a metal-oxide-semiconductor field-effect transistor (MOSFET), and a diode. The power conversion is executed such that these power semiconductor elements are switched to be turned on and turned off.

An important issue is heat releasing for such a power semiconductor element since heat generation caused upon the switching decreases reliability of the product. A ceramic insulated substrate is typically used as a structure for dealing with the heat releasing. The ceramic insulated substrate has a structure including a ceramic base made from alumina, aluminum nitride, or silicon nitride, and conductor foil such as aluminum or copper bonded to both surfaces of the ceramic base. The power semiconductor element is bonded to the conductor foil bonded to the ceramic insulated substrate by use of solder or metallic sintered material. A heat-releasing base plate made from aluminum or copper is bonded to the other conductor foil on the opposite side of the power semiconductor element by use of solder or metallic sintered material, so as to release the heat generated in the power semiconductor element. The structure using the ceramic insulated substrate has a problem of difficulty in decreasing a thickness of the ceramic insulated substrate itself and a problem of a reduction in reliability regarding the bonded parts because of thermal stress derived from a difference in a coefficient of thermal expansion between the components. The demand for a structure using a resin insulated substrate thus has grown instead.

The structure using the resin insulated substrate is obtained such that conductor foil such as aluminum or copper is laminated and bonded to a heat-releasing base plate together with a resin insulating layer containing heat-conductive filler such as alumina, aluminum nitride, or boron nitride mixed to resin mainly containing epoxy resin, and a power semiconductor element is then bonded to a surface of the conductor foil provided with a particular pattern by etching by use of solder or sintered material. The structure using the resin insulated substrate can reduce the thermal stress since the difference in the coefficient of thermal expansion between the components can be decreased, and can also contribute to a reduction in the thickness of the resin insulating layer and decrease the number of bonding layers, so as to achieve a heat-releasing structure with high reliability and low heat resistance.

The power semiconductor module with the structure using the resin insulated substrate needs to ensure a breakdown voltage while having a reduced thickness of the resin insulating layer as thinner as possible. To deal with such requirements, JP H11-8450 A and JP 2003-303940 A disclose a two-layer structure of resin insulating layers in which a modulus coefficient of elasticity and a content of filler contained are varied so as to ensure both the breakdown voltage and the heat-releasing performance. JP H11-67994 A discloses a structure in which filler is contained in polyimide-based resin to have a two-layer structure together with epoxy-based resin so that voids caused by the inclusion of the filler in the polyimide-based resin are filled with the epoxy-based resin, so as to provide a resin insulating layer with a density increased and the heat-releasing performance improved.

JP2011-035349 A discloses a semiconductor device including a first passivation film and a second passivation film deposited straight in a belt-like state on the first passivation film, wherein the first passivation film is made from polyimide-based resin, and the second passivation film is made from polyimide-based resin having a lower water-absorption rate than epoxy-based resin that is material used for a sealing film.

JP H5-090946 U discloses a structure in which a first dice-bond material for fixing a semiconductor element and a die pad together is used only in a part adjacent to a lower side of a pad for metal thin-wire fixation on the semiconductor element, and a second dice-bond material is applied to the other parts, wherein epoxy-based material having a high water-absorption rate is used as the first dice-bond material, and silicone-based material having a low water-absorption rate is used as the second dice-bond material.

JP 2008-047652 A discloses a structure in which a semiconductor chip includes an electrode pad metal, a first passivation film, a second passivation film, two metal films, and bumps, in which the first passivation film including a nitride film and polyimide has a lower water-absorption rate than the second passivation film including polyimide and epoxy resin.

JP 2021-158304 A discloses a semiconductor device including an insulated circuit substrate with a structure including an insulating plate and a plurality of circuit patterns provided on the front surface of the insulating plate with gaps interposed, wherein the gaps between the respective circuit patterns around the corners are filled with resin.

The structure disclosed in each of JP H11-8450 A and JP 2003-303940 A, however, inevitably decreases the heat-releasing performance in association with a decrease in the content of the filler that contributes to thermal conductivity, including a case of decreasing the modulus coefficient of elasticity.

The structure disclosed in JP H11-67994 A has a problem with the epoxy-based resin that does not contain filler contributing to thermal conductivity, and the presence of the layer not containing filler leads to a decrease in heat-releasing performance regardless of whether the layer is quite thin.

JP H11-8450 A, JP 2003-303940 A, and JP H11-67994 A fail to disclose or suggest any teaching about a sealing material. The sealing material, if used, includes silicone gel and epoxy-based resin that typically have the characteristics of having high heat resistance but also have a high water-absorption rate. Further, the resin insulating layer of the resin insulated substrate has a configuration that typically contains thermal-conductive filler in the epoxy-based resin. A DC voltage, when applied to such a resin insulating layer, easily causes migration from a heat-releasing base plate or conductor foil of aluminum or copper because of a OH group of absorbed moisture, and thus leads to a decrease in breakdown voltage. While some of epoxy-based resin typically used for the resin insulating layer of the resin insulated substrate has a low water-absorption rate, the epoxy-based resin usually contains a large amount of thermal-conductive filler in order to increase the thermal conductivity, and thus has an influence on the migration since the epoxy base material actually absorbs moisture although the water-absorption rate is seemingly low.

### SUMMARY OF THE INVENTION

In view of the foregoing problems, the present invention provides a semiconductor device having a configuration capable of efficiently releasing heat generated in a power semiconductor element, and suppressing migration from a heat-releasing base plate or conductor foil of a resin insulated substrate.

An aspect of the present invention inheres in a semiconductor device including: a resin insulated substrate including a first rein insulating layer, a conductor base provided on one of main surfaces of the first resin insulating layer, and a conductor foil provided on another main surface of the first resin insulating layer; a power semiconductor element bonded to the conductor foil; a case surrounding an outer circumference of the resin insulated substrate; a sealing resin provided inside the case to seal the power semiconductor element; and a second resin insulating layer provided between the first resin insulating layer and the sealing resin and having a lower water-absorption rate than the sealing resin.

### BRIEF DESCRIPTION OF THE DRAWINGS

FIG. 1 is a schematic cross-sectional view illustrating a semiconductor device according to a first embodiment;

FIG. 2 is a schematic plan view illustrating the semiconductor device according to the first embodiment:

FIG. 3 is a schematic cross-sectional view illustrating a semiconductor device according to a second embodiment;

FIG. 4 is a schematic cross-sectional view illustrating a semiconductor device according to a third embodiment;

FIG. 5 is a schematic cross-sectional view illustrating a semiconductor device according to a fourth embodiment;

FIG. 6 is a schematic cross-sectional view illustrating a semiconductor device according to a fifth embodiment; and

FIG. 7 is a schematic cross-sectional view illustrating a semiconductor device according to a sixth embodiment.

### DETAILED DESCRIPTION

With reference to the drawings, first to sixth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present invention. For example, when observing an object rotated by 90 degrees, the “upper and lower” are converted to “left and right” to be read, and when observing an object rotated by 180 degrees, the “upper and lower” are read reversed, which should go without saying.

In the following descriptions, a “first main surface” and a “second main surface” of each component are the respective main surfaces opposed to each other. For example, when the “first main surface” is a top surface, the “second main surface” is a bottom surface. When the “first main surface” is a bottom surface, the “second main surface” is a top surface. The “first main surface” and the “second main surface” can also be referred to as “one of the main surfaces” and the “other main surface” respectively. In addition, the “top surface” and the “bottom surface” can also be referred to as a “front surface” and a “rear surface” respectively.

### First Embodiment

<Structure of Semiconductor Device>

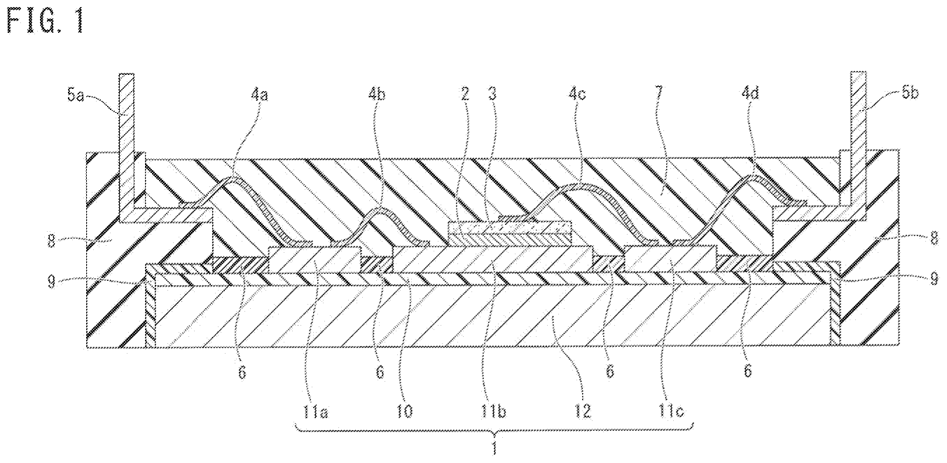

A semiconductor device (a power semiconductor module) according to a first embodiment includes a resin insulated substrate 1, as illustrated in FIG. 1. The resin insulated substrate 1 includes a conductor base (a heat-releasing base plate) 12, a resin insulating layer (a first resin insulating layer) 10 deposited on the top surface side of the conductor base 12, and conductor foils 11a to 11c deposited on the top surface side of the first resin insulating layer 10.

A thickness of the conductor base 12 is in a range of about 1 millimeter or greater and 10 millimeters or less, for example, but is not limited to this range and may be determined as appropriate. The conductor base 12 as used herein can be made from material having high heat conductivity, such as copper (Cu), aluminum (Al), composite material (AlSiC) of Al and silicon carbide (SiC), and composite material (MgSiC) of magnesium (Mg) and SiC. The surface of the conductor base 12 may be plated with nickel (Ni), for example. The conductor base 12 may include Cu or Al not subjected to plating treatment in view of a difference in a coefficient of thermal expansion from other members and in view of costs.

A thickness of the first resin insulating layer 10 is in a range of about 0.05 millimeters or greater and 0.5 millimeters or less, for example, but is not limited to this range and may be determined as appropriate. The determination of the thickness of the first resin insulating layer 10 depends on a rated voltage of the power semiconductor module. While the thickness of the first resin insulating layer 10 needs to be increased as the rated voltage of the power semiconductor module is higher, the thickness is preferably decreased to a minimum so as to reduce heat resistance.

The first resin insulating layer 10 is obtained such that filler (heat-conductive filler) serving as a filling agent is added (mixed) to resin. The content (the filled percentage) of the filler contained in the first resin insulating layer 10 is in a range of about 50% by volume or greater and 90% by volume or smaller, for example. A water-absorption rate of the first resin insulating layer 10 depends on the type and the content of the filler. The inclusion of the filler can vary the water-absorption rate of the first resin insulating layer 10, which can be either higher or lower than that of the resin itself included in the first resin insulating layer 10, depending on the type of the filler to be used.

The resin included in the first resin insulating layer 10 can be resin having high heat-resistant and insulating properties, such as epoxy-based resin, silicone-based resin, cyanate-based resin, maleimide-based resin, polyimide-based resin, or polyamide-based resin, but is not limited to those listed above. The epoxy-based resin is preferably used for the first resin insulating layer 10 in view of mechanical strength or compatibility of the filler to be mixed.

The first resin insulating layer 10 may include one or more kinds of inorganic filler of an oxide such as silica (SiO₂) and alumina (Al₂O₃) or a nitride such as aluminum nitride (AlN), silicon nitride (Si₃N₄), and boron nitride (BN) in order to decrease the difference in the coefficient of thermal expansion from the conductor base 12 and the conductor foils 11a to 11c. In other words, either one kind of filler may be used or several kinds of filler may be mixed together. The first resin insulating layer 10 preferably includes filler of hexagonal boron nitride particularly in order to enhance the heat conductivity.

The heat conductivity of the first resin insulating layer 10 is in a range of about 10 W/m·K or greater and 20 W/m·K or less, for example, but is not limited to this range and may be determined as appropriate. The water-absorption rate of the first resin insulating layer 10 is in a range of about 0.5% or greater and 2% or less, for example, but is not limited to this range and may be determined as appropriate. The term “water-absorption rate” of the first resin insulating layer 10 as used herein refers to a water-absorption rate of the entire first resin insulating layer 10 including the resin and the filler. The water-absorption rate of the first resin insulating layer 10 can be adjusted as appropriate by the choice of the type of the resin and the filler and the content of the filler included in the first resin insulating layer 10. The respective water-absorption rates of the first resin insulating layer 10 and the other members can be measured such that a sample form is prepared in accordance with JIS C6481.

The respective conductor foils 11a to 11c have a particular circuit pattern determined as appropriate. The respective conductor foils 11a to 11c have a thickness of about 0.1 millimeters or greater, and preferably have a thickness of about 0.5 millimeters or greater, for example. The determination of the thickness of the respective conductor foils 11a to 11c depends on a current capacity of the power semiconductor module. The respective conductor foils 11a to 11c can be made from the same material as the conductor base 12 in view of the difference in the coefficient of thermal expansion, or may be made from material different from that of the conductor base 12 instead. The material used for the conductor foils 11a to 11c is preferably copper (Cu) that does not need to be subjected to plating treatment. While FIG. 1 illustrates the case in which the side surfaces of the conductor foils 11a to 11c are substantially perpendicular to the top surfaces and the bottom surfaces of the conductor foils 11a to 11c, but the power semiconductor module is not limited to this case as illustrated.

A power semiconductor element (a semiconductor chip) 3 is deposited on the top surface of the conductor foil 11b via a bonding material 2 such as solder or sintered material. The solder used as the bonding material 2 can be lead-free solder such as thin-antimony-based (Sn—Sb), thin-copper-based (Sn—Cu), thin-copper-silver-based (Sn—Cu—Ag), tin-silver-based (Sn—Ag), thin-silver-copper-based (Sn—Ag—Cu), thin-silver-bismuth-copper-based (Sn—Ag—Bi—Cu), tin-indium-silver-bismuth-based (Sn—In—Ag—Bi), tin-zinc-based (Sn—Zn), tin-zinc-bismuth-based (Sn—Zn—Bi), tin-bismuth-based (Sn—Bi), or tin-indium-based (Sn—In) solder, or leaded solder such as tin-lead-based (Sn—Pb) solder, for example. The sintered material used as the bonding material 2 is obtained such that a sintered sheet or conductive paste is sintered, in which metallic particles such as gold (Au), silver (Ag), or copper (Cu) having a fine particle diameter of about several nanometers to several micrometers are dispersed in an organic component (a binder).

The power semiconductor element 3 may be any of a field-effect transistor (FET) such as a MOSFET, an insulated gate bipolar transistor (IGBT), a static induction (SI) thyristor, or agate turn-off ((GTO) thyristor. The power semiconductor element 3, in the case of the MOSFET, includes a semiconductor substrate, a first main electrode (a drain electrode) deposited on the bottom surface side of the semiconductor substrate, and a second main electrode (a source electrode) and a control electrode (a gate electrode) deposited on the top surface side of the semiconductor substrate. The semiconductor substrate is made from silicon (Si), silicon carbide (SiC), gallium nitride (GaN), or gallium oxide (Ga₂O₃), for example. The arranged position of the power semiconductor element 3 and the number of the power semiconductor elements can be determined as appropriate. While FIG. 1 illustrates the case of including the single power semiconductor element 3, a plurality of power semiconductor elements may be arranged in parallel, or a 2-in-1 type may be applied to the module equipped with a pair of power semiconductor elements.

The conductor foil 11b to which the drain electrode on the bottom surface side of the power semiconductor element 3 is bonded is connected to the conductor foil 11a via a wire 4b. The conductor foil 11a is connected via a wire 4a to a conductor terminal 5a serving as an electrode external-extraction part. The source electrode on the top surface side of the power semiconductor element 3 is connected to the conductor foil 11c via a wire 4c. The conductor foil 11c is connected via a wire 4d to a conductor terminal 5b serving as an electrode external-extraction part. The respective wires 4a to 4d are made from aluminum (Al) or copper (Cu). Instead of the respective wires 4a to 4d, a lead frame wire, a ribbon wire, or a printed substrate to which pin terminals are inserted may be used. FIG. 1 omits the illustration of a control wire and the like connected to the gate electrode of the power semiconductor element 3.

The respective conductor terminals 5a and 5b are integrated with a case 8. The conductor terminals 5a and 5b may be further elongated to be bent toward the conductor foils 11a and 11c so as to be connected directly to the conductor foils 11a and 11c instead, without the use of the wire 4a or the wire 4d. When the conductor base 12 and the conductor foils 11a to 11c include copper (Cu), the use of Cu for the wires 4a to 4d or the lead frame wires and also for the conductor terminals 5a and 5b can eliminate the difference in the coefficient of thermal expansion between the components, so as to reduce a stress derived from the difference in the coefficient of thermal expansion accordingly.

The case 8 has a larger outer circumferential size than the resin insulated substrate 1. The case 8 covers the respective side surfaces of the conductor base 12 and the first resin insulating layer 10 of the resin insulated substrate 1 and the top surfaces of the end parts of the first resin insulating layer 10. The case 8 covering the side surfaces of the resin insulated substrate 1 can avoid penetration of moisture into the first resin insulating laver 10 of the resin insulated substrate 1. The case 8 surrounds the outermost circumference of the respective patterns of the conductor foils 11a to 11c of the resin insulated substrate 1. The first resin insulating layer 10 is partly exposed on the regions between the respective patterns of the conductor foils 11a to 11c and between the outermost circumference of the patterns of the conductor foils 11a to 11c and the case 8.

The case 8 can be made from thermosetting resin such as phenolic resin, polyester, and epoxy resin, or thermoplastic resin such as polyphenylene sulfide (PPS), polybutylene terephthalate (PBT), polyamide, and ABS resin. Mixing filler such as glass fiber to the resin included in the case 8 to lead the coefficient of thermal expansion to approximate to that of the resin insulated substrate 1, can reduce the stress derived from the difference in the coefficient of thermal expansion.

The case 8 and the resin insulated substrate 1 are bonded together via an adhesive layer 9. The adhesive layer 9 to be used can be made from an adhesive having high heat resistance and a low water-absorption rate, such as silicone, cyanate, phenol, and polyimide.

The case 8 is filled with sealing resin 7. The sealing resin 7 mainly seals the conductor foils 11a to 11c, the bonding material 2, the power semiconductor element 3, and the wires 4a to 4d. The sealing resin 7 to be used can be insulating resin such as thermosetting silicone gel and epoxy resin. A water-absorption rate of the sealing resin 7 is in a range of about 0.5% or greater and 2% or less, but is not limited to this range and determined as appropriate.

The exposed parts of the top surface of the first resin insulating layer 10 of the resin insulated substrate 1 not covered by the conductor foils 11a to 11c or the case 8 are provided with a second resin insulating layer 6. The second resin insulating layer 6 is interposed between the first resin insulating layer 10 and the sealing resin 7. The second resin insulating layer 6 is in contact with the side surfaces of the respective conductor foils 11a to 11c. The second resin insulating layer 6 is also in contact with the side surfaces of the adhesive layer 9.

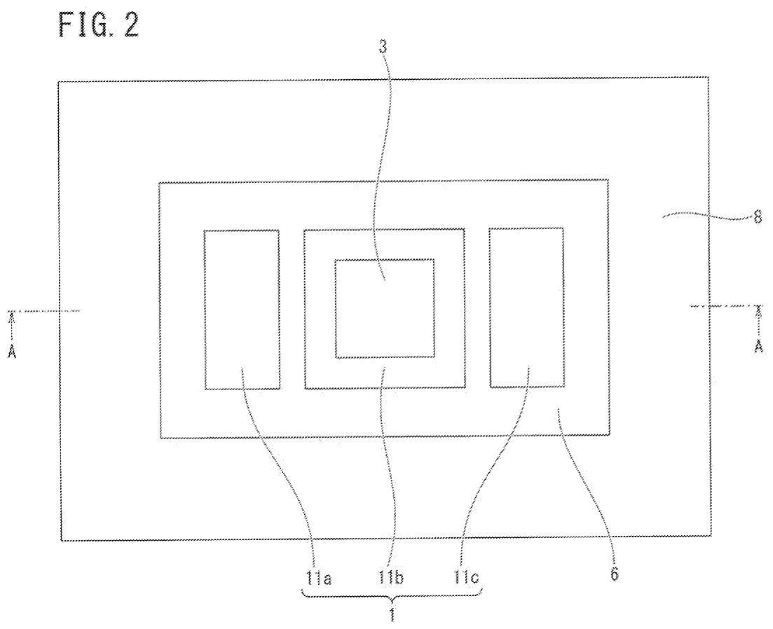

FIG. 2 is a plan view illustrating the semiconductor device according to the first embodiment. FIG. 1 corresponds to the cross section as viewed from direction A-A in FIG. 2. FIG. 2 omits the illustration of the sealing resin 7, the wires 4a to 4d, and the conductor terminals 5a and 5b illustrated in FIG. 1. The respective conductor foils 11a to 11c have a rectangular planar pattern. The second resin insulating layer 6 is provided between the conductor foils 11a to 11c and the case 8 so as to surround the respective circumferences of the conductor foils 11a to 11c.

The second resin insulating layer 6 as used herein can be made from resin having a low water-absorption rate and having high adhesion to the sealing resin 7. The second resin insulating layer 6 includes at least one kind of resin selected from the group consisting of liquid crystal polymer, silicone, polyamide imide, polyimide, and para-xylene polymer, for example. In other words, the second resin insulating layer 6 may only include one resin as listed above, or may include some of them mixed together. The second resin insulating layer 6 may include the resin to which filler is mixed, or may be made from only the resin without including filler. The filler, if included in the second resin insulating layer 6, is preferably organic filler having high adhesion to the first resin insulating layer 10 without impeding a watertight effect.

The water-absorption rate of the second resin insulating layer 6 is about 0.1% or lower, for example, but is not limited to this case. The water-absorption rate of the second resin insulating layer 6 as used herein refers to that of the entire second resin insulating layer 6. When the second resin insulating layer 6 only includes resin, the water-absorption rate refers to that of the resin of the second resin insulating layer 6. When the second resin insulating layer 6 includes resin and filler, the water-absorption rate refers to that of the entire second resin insulating layer 6 including the resin and the filler. The water-absorption rate of the second resin insulating layer 6 can be adjusted as necessary such that the type of the resin and the filler, the presence or absence of the filler, and the content of the filler in the second resin insulating layer 6 are determined as appropriate.

The water-absorption rate of the second resin insulating layer 6 is lower than that of the sealing resin 7. This configuration can block or reduce the penetration of moisture from the sealing resin 7 into the first resin insulating layer 10. The water-absorption rate of the second resin insulating layer 6 is also preferably lower than that of the first resin insulating layer 10. This configuration can block or reduce the penetration of moisture from the sealing resin 7 into the first resin insulating layer 10 more effectively. The water-absorption rate of the second resin insulating layer 6 may be higher than that of the first resin insulating layer 10 instead.

The resin included in the second resin insulating layer 6 may be the same as that included in the first resin insulating layer 10. In such a case, the combination of the second resin insulating layer 6 not including filler and the first resin insulating layer 10 including filler, for example, can improve the heat-releasing performance of the first resin insulating layer 10 more than that of the second resin insulating layer 6, and can lead the water-absorption rate of the first resin insulating layer 10 to be higher than that of the second resin insulating layer 6. The case in which the second resin insulating layer 6 includes the same resin as the first resin insulating layer 10 can enhance the adhesion between the second resin insulating layer 6 and the first resin insulating layer 10.

The resin included in the second resin insulating layer 6 may have a higher water-absorption rate than the resin included in the first resin insulating layer 10. In such a case, the combination of the second resin insulating layer 6 not including filler and the first resin insulating layer 10 including filler, for example, can improve the heat-releasing performance of the first resin insulating layer 10 more than that of the second resin insulating layer 6, and can lead the water-absorption rate of the first resin insulating layer 10 to be higher than that of the second resin insulating layer 6.

The water-absorption rate of the second resin insulating layer 6 is preferably lower than that of the adhesive layer 9. The second resin insulating layer 6 having a lower water-absorption rate than the adhesive layer 9 can avoid the penetration of moisture from the outside through the adhesive layer 9.

The second resin insulating layer 6 preferably has a thickness of about 5 micrometers or greater in order to effectively exhibit the watertight effect. While FIG. 1 illustrates the case in which the second resin insulating layer 6 has a smaller thickness than the respective conductor foils 11a to 11c, the second resin insulating layer 6 may either have the same thickness as or have a greater thickness than the respective conductor foils 11a to 11c. The second resin insulating layer 6, when having a greater thickness than the respective conductor foils 11a to 11c, may be in contact with the top surfaces of the conductor foils 11a to 11c, the power semiconductor element 3, the respective wires 4a to 4d, and the like. The thickness of the second resin insulating layer 6 is preferably greater than that of the adhesive layer 9 in order to block or reduce the penetration of moisture through the adhesive layer 9.

The semiconductor device according to the first embodiment, which uses the resin insulated substrate 1 having high breakdown voltage and high resistance to heat, can efficiently release heat generated in the power semiconductor element 3. In addition, the use of the second resin insulating layer 6 provided between the first resin insulating layer 10 of the resin insulated substrate 1 and the sealing resin 7 and having the lower water-absorption rate than the sealing resin 7 can block or reduce the penetration of moisture from the sealing resin 7 into the first resin insulating layer 10 regardless of whether a DC voltage is applied to the first resin insulating layer 10, so as to avoid migration of the conductor from the conductor base 12 or the respective conductor foils 11a to 11c. This configuration can achieve the power semiconductor module having high heat-releasing efficiency and long-term reliability.

<Method of Manufacturing Semiconductor Device>

An example of a method of manufacturing the semiconductor device according to the first embodiment is described below with reference to FIG. 1. The method of manufacturing the semiconductor device described below is one of examples, and it should be understood that the semiconductor device can be manufactured by various methods including modified examples of this embodiment within the scope of the appended claims.

First, to prepare the resin insulated substrate 1 illustrated in FIG. 1, a conductor base, a resin insulating layer, and a conductor foil each having a large size are laminated together, and then heated and further pressed as necessary in the plane direction corresponding to the laminated direction so as to be bonded together. This step may be executed in an inert gas atmosphere or in a vacuum. The conductor foil is subjected to masking by photoresist to form an appropriate pattern by etching, and the photoresist mask is then removed. The pattern of the conductor foil is formed such that the end part of the outermost circumference is located on the inside of the end part of the conductor base, so as to keep an insulated distance between the conductor foil and the conductor base. The pattern is then cut into a size conforming to the power semiconductor module. The resin insulated substrate 1 is thus formed in which the conductor base 12, the resin insulating layer, and the conductor foils 11a to 11c illustrated in FIG. 1 are integrated together.

Next, the power semiconductor element 3 is bonded onto the conductor foil 11b via the bonding material 2 of solder or sintered material, for example. The source electrode of the power semiconductor element 3 and the conductor foil 11c are connected to each other by wire bonding with the wire 4c, and the conductor foil 11b and the conductor foil 11a are connected to each other by wire bonding with the wire 4b. The conductor terminal 5a and the conductor foil 11a are connected to each other by wire bonding with the wire 4a, and the conductor terminal 5b and the conductor foil 11c are connected to each other by wire bonding with the wire 4d. The respective conductor terminals 5a and 5b are subjected to insert molding when the case 8 is formed so as to be integrated with the case 8.

The lead frames, when used instead of the wires 4a to 4d, may be bonded by use of bonding material such as solder or sintered material simultaneously with the step of bonding the conductor foil 11b to the power semiconductor element 3 together. The conductor terminals 5a and 5b, when directly connected onto the conductor foils 11a and 11c, may be electrically bonded to the conductor foils 11a and 11c by soldering, ultrasonic welding, or laser welding, for example.

Next, the case 8 and the resin insulated substrate 1 are attached together by the adhesive layer 9. Next, the exposed parts on the top surface of the first resin insulating layer 10 of the resin insulated substrate 1 are coated with the second resin insulating layer 6. The coating with the second resin insulating layer 6 can be made by a spraying method or a dispensing method, or may be made by the application of para-xylene polymer as a “parylene film” by a vapor deposition method. The area coated with the second resin insulating layer 6 may extend to the respective conductor foils 11a to 11c, the power semiconductor element 3, and the wiring members such as the wires 4a to 4d. A solvent is then heated or left for a predetermined period of time to be got rid of, so as to solidify the second resin insulating layer 6 and volatilize moisture having adhered during the coating step.

Next, the sealing resin 7 is cast in the part surrounded by the case 8 and the resin insulated substrate 1. The casting of the sealing resin 7 is executed such that the sealing resin 7 and the power semiconductor module are heated to lower the viscosity of the sealing resin 7, or the casting of the sealing resin 7 is executed in a vacuum, so as to inject the sealing resin 7 into the entire space to seal it with no voids caused. Before the injection of the sealing resin 7, the sealing resin 7 in a liquid state itself is subjected to vacuum defoaming, and is further stirred so as to be completely defoamed in a vacuum, which can avoid the cause of voids more accurately. In addition, the injection of the sealing resin 7 in a liquid state is executed while ultrasonic oscillation is applied to the power semiconductor module, so as to completely suppress the cause of voids. The semiconductor device according to the first embodiment as illustrated in FIG. 1 and FIG. 2 is thus completed.

### Second Embodiment

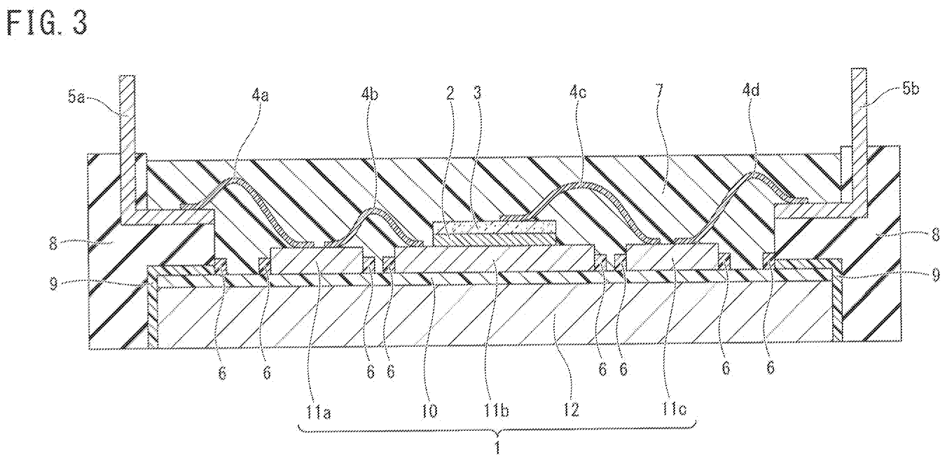

A semiconductor device according to a second embodiment differs from the semiconductor device according to the first embodiment in that the second resin insulating layer 6 is not entirely provided between the first resin insulating layer 10 and the sealing resin 7 but is selectively provided at positions in contact with the side surfaces of the respective conductor foils 11a to 11c, as illustrated in FIG. 3. The second resin insulating layer 6 is arranged to surround the respective circumferences of the conductor foils 11a to 11c.

The second resin insulating layer 6 is also selectively provided at positions in contact with the side surfaces of the adhesive layer 9. The second resin insulating layer 6 is provided to cover the entire side surfaces of the adhesive layer 9 along the inside of the case 8. The second resin insulating layer 6 is not provided either in the middle of the parts between the respective patterns of the conductor foils 11a to 11c or in the middle of the parts between the conductor foils 11a to 11c and the case 8, while the sealing resin 7 is in contact with the first resin insulating layer 10. The other elements of the semiconductor device according to the second embodiment have substantially the same structures as those of the semiconductor device according to the first embodiment, and overlapping explanations are not repeated below.

The configuration of the semiconductor device according to the second embodiment tends to cause migration at the end parts of the respective conductor foils 11a to 11c because an electric field concentrates on the end parts when a DC voltage is applied. The use of the second resin insulating layer 6 selectively provided at the positions in contact with the side surfaces of the respective conductor foils 11a to 11c, however, can block or reduce the penetration of moisture from the sealing resin 7 into the end parts of the respective conductor foils 11a to 11c at which the migration tends to be easily caused. In addition, the use of the second resin insulating layer 6 selectively provided at the positions in contact with the side surfaces of the adhesive layer 9 can also block or reduce the penetration of moisture from the outside through the adhesive layer 9.

### Third Embodiment

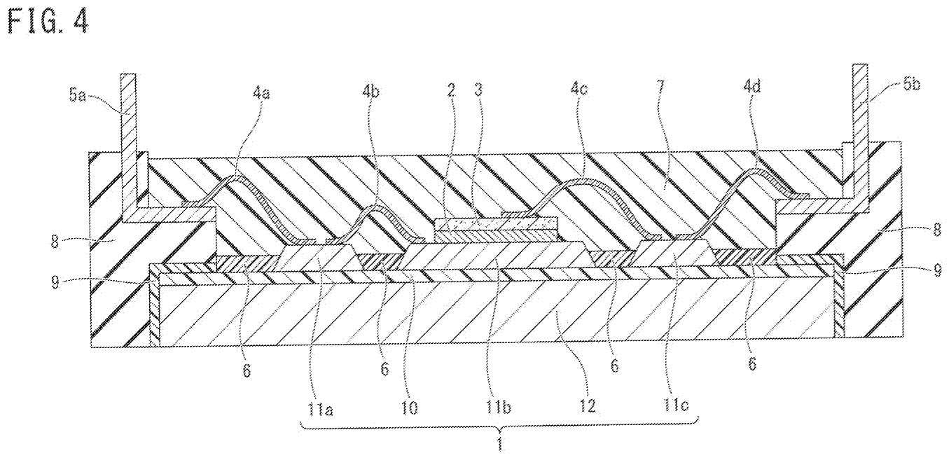

A semiconductor device according to a third embodiment differs from the semiconductor device according to the first embodiment in that the side surfaces of the respective conductor foils 11a to 11c are not perpendicular to the top surface or the bottom surface of the respective conductor foils 11a to 11c, but the respective conductor foils 11a to 11c have a tapered shape (a regular tapered shape) tapered toward the top surface and having a width increasing toward the lower side, as illustrated in FIG. 4. The width of the top surface of the respective conductor foils 11a to 11c is smaller than the width of the bottom surface of the respective conductor foils 11a to 11c. The other elements of the semiconductor device according to the third embodiment have substantially the same structures as those of the semiconductor device according to the first embodiment, and overlapping explanations are not repeated below.

The semiconductor device according to the third embodiment with the configuration of using the second resin insulating layer 6 provided between the first resin insulating layer 10 of the resin insulated substrate 1 and the sealing resin 7 and having the lower water-absorption rate than the sealing resin 7, can block or reduce the penetration of moisture from the sealing resin 7 into the first resin insulating layer 10 regardless of whether a DC voltage is applied to the first resin insulating layer 10, so as to avoid migration of the conductor from the conductor base 12 or the respective conductor foils 11a to 11c, as in the case of the semiconductor device according to the first embodiment.

In addition, the regular tapered shape of the side surfaces of the respective conductor foils 11a to 11c can avoid the entrance of bubbles in the second resin insulating layer 6 during the preparation more reliably than the case in which the side surfaces of the respective conductor foils 11a to 11c are perpendicular to the top surface and the bottom surface of the respective conductor foils 11a to 11c.

### Fourth Embodiment

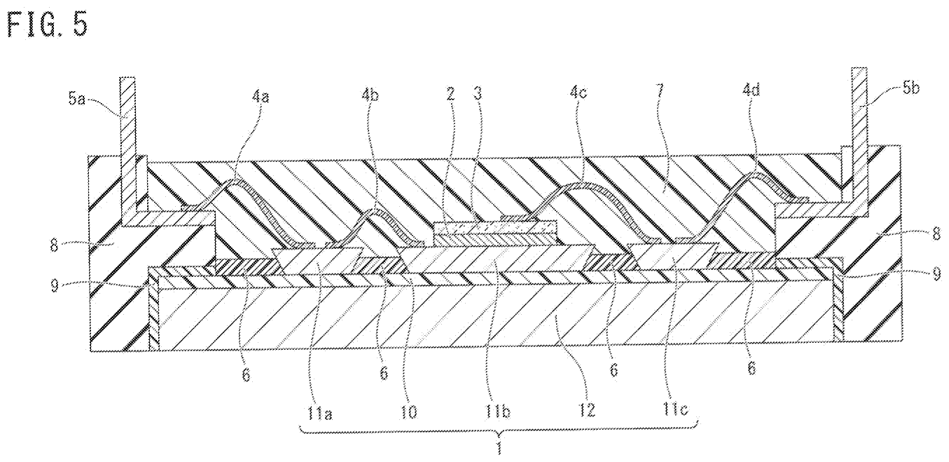

A semiconductor device according to a fourth embodiment differs from the semiconductor device according to the first embodiment in that the side surfaces of the respective conductor foils 11a to 11c are not perpendicular to the top surface or the bottom surface of the respective conductor foils 11a to 11c, but the respective conductor foils 11a to 11c have a tapered shape (an inverse tapered shape) tapered toward the bottom surface and having a width decreasing toward the lower side, as illustrated in FIG. 5. The width of the top surface of the respective conductor foils 11a to 11c is greater than the width of the bottom surface of the respective conductor foils 11a to 11c. The other elements of the semiconductor device according to the fourth embodiment have substantially the same structures as those of the semiconductor device according to the first embodiment, and overlapping explanations are not repeated below.

The inverse tapered shape of the side surfaces of the respective conductor foils 11a to 11c tends to cause bubbles in the second resin insulating layer 6 during the manufacture of the semiconductor device according to the fourth embodiment more easily than the case in which the side surfaces are perpendicular to the top surface and the bottom surface of the respective conductor foils 11a to 11c or the case of having the regular tapered shape. To deal with this, preparing the second resin insulating layer 6 in a vacuum can avoid the entrance of bubbles in the second resin insulating layer 6 reliably.

The semiconductor device according to the fourth embodiment with the configuration of using the second resin insulating layer 6 provided between the first resin insulating layer 10 of the resin insulated substrate 1 and the sealing resin 7 and having the lower water-absorption rate than the sealing resin 7, can block or reduce the penetration of moisture from the sealing resin 7 into the first resin insulating layer 10 regardless of whether a DC voltage is applied to the first resin insulating layer 10, so as to avoid migration of the conductor from the conductor base 12 or the respective conductor foils 11a to 11c, as in the case of the semiconductor device according to the first embodiment.

In addition, the inverse tapered shape of the side surfaces of the respective conductor foils 11a to 11c, which leads the respective corners defined by the side surfaces and the bottom surface of the respective conductor foils 11a to 11c to have an obtuse angle, can decrease an electric-field concentration more than the case in which the respective corners have a right angle or an acute angle. This can suppress the migration of the conductor from the conductor base 12 or the respective conductor foils 11a to 11c more reliably.

### Fifth Embodiment

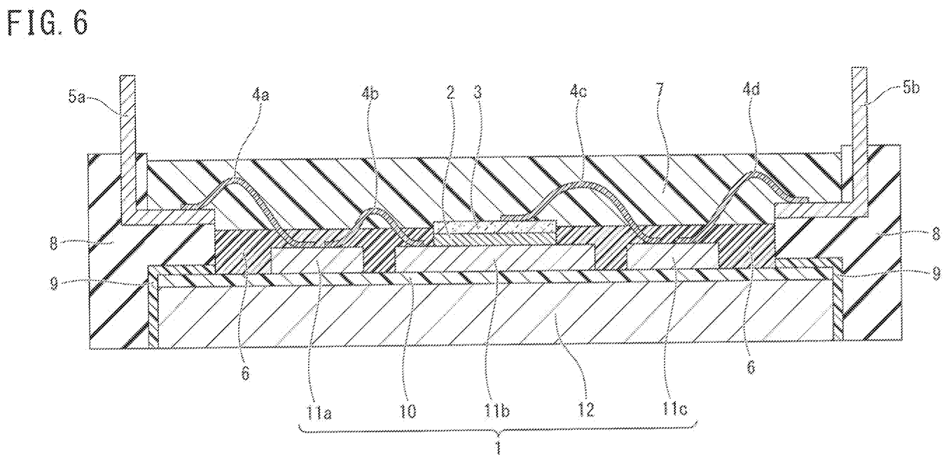

A semiconductor device according to a fifth embodiment differs from the semiconductor device according to the first embodiment in that the thickness of the second resin insulating layer 6 is greater than the total of the thickness of the respective conductor foils 11a to 11c and the thickness of the bonding material 2, as illustrated in FIG. 6. The second resin insulating layer 6 is provided to cover the side surfaces of the bonding material 2 and further partly cover the side surfaces of the power semiconductor element 3. The other elements of the semiconductor device according to the fifth embodiment have substantially the same structures as those of the semiconductor device according to the first embodiment, and overlapping explanations are not repeated below.

The semiconductor device according to the fifth embodiment with the configuration of using the second resin insulating layer 6 provided between the first resin insulating layer 10 of the resin insulated substrate 1 and the sealing resin 7 and having the lower water-absorption rate than the sealing resin 7, can block or reduce the penetration of moisture from the sealing resin 7 into the first resin insulating layer 10 regardless of whether a DC voltage is applied to the first resin insulating layer 10, so as to avoid migration of the conductor from the conductor base 12 or the respective conductor foils 11a to 11c, as in the case of the semiconductor device according to the first embodiment.

In addition, the second resin insulating layer 6, which has the thickness greater than the total of the thickness of the respective conductor foils 11a to 11c and the thickness of the bonding material 2 so as to cover the side surfaces of the bonding material 2, can block or reduce the penetration of moisture from the sealing resin 7 into the side surfaces of the bonding material 2, avoiding migration from the bonding material 2 accordingly. This configuration is particularly effective, for example, in a case of using sintered material that tends to cause migration such as silver (Ag).

### Sixth Embodiment

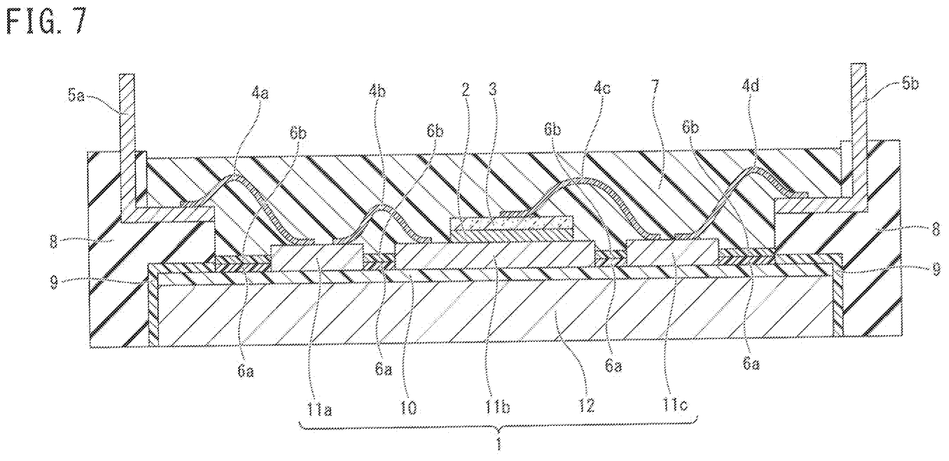

A semiconductor device according to a sixth embodiment differs from the semiconductor device according to the first embodiment in that the second resin insulating layer (6a. 6b) includes a plurality of resin insulating layers, as illustrated in FIG. 7. The second resin insulating layer (6a, 6b) includes a lower-side resin insulating layer 6a and an upper-side resin insulating layer 6b deposited on the lower-side resin insulating layer 6a.

The lower-side resin insulating layer 6a and the upper-side resin insulating layer 6b each have a lower water-absorption rate than the sealing resin 7. The lower-side resin insulating layer 6a and the upper-side resin insulating layer 6b have different configurations, but preferably include the same kind of material in order to improve the adhesion. The second resin insulating layer may include three or more resin insulating layers stacked together. The other elements of the semiconductor device according to the sixth embodiment have substantially the same structures as those of the semiconductor device according to the first embodiment, and overlapping explanations are not repeated below.

The semiconductor device according to the sixth embodiment with the configuration in which the second resin insulating layer (6a, 6b) includes the plural resin insulating layers provided between the first resin insulating laver 10 of the resin insulated substrate 1 and the sealing resin 7, can also block or reduce the penetration of moisture into the first resin insulating layer 10, so as to avoid migration of the conductor from the conductor base 12 or the respective conductor foils 11a to 11c.

### Other Embodiments

As described above, the invention has been described according to the first to sixth embodiments, but it should not be understood that the description and drawings implementing a portion of this disclosure limit the invention. Various alternative embodiments of the present invention, examples, and operational techniques will be apparent to those skilled in the art from this disclosure.

The configurations disclosed in the first to sixth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification

What is claimed is:

1. A semiconductor device comprising:
a resin insulated substrate including a first rein insulating layer, a conductor base provided on one of main surfaces of the first resin insulating layer, and a conductor foil provided on another main surface of the first resin insulating layer;
a power semiconductor element bonded to the conductor foil;
a case surrounding an outer circumference of the resin insulated substrate;
a sealing resin provided inside the case to seal the power semiconductor element; and
a second resin insulating layer provided between the first resin insulating layer and the sealing resin and having a lower water-absorption rate than the sealing resin.

2. The semiconductor device of claim 1, wherein the second resin insulating layer includes at least one kind of resin selected from liquid crystal polymer, silicone, polyamide imide, polyimide, and para-xylene polymer.

3. The semiconductor device of claim 1, wherein the first resin insulating layer includes filler.

4. The semiconductor device of claim 1, wherein the water-absorption rate of the second resin insulating layer is lower than that of the first resin insulating layer.

5. The semiconductor device of claim 1, wherein the second resin insulating layer has a smaller thickness than the conductor foil.

6. The semiconductor device of claim 1, wherein:
a part of the case is bonded to a top surface of an end part of the first resin insulating layer via an adhesive layer; and
the second resin insulating layer is provided to cover a side surface of the adhesive layer.

7. The semiconductor device of claim 1, wherein the second resin insulating layer is selectively provided at a position in contact with a side surface of the conductor foil.

8. The semiconductor device of claim 1, wherein the conductor foil has a side surface having a regular tapered shape with a width gradually increasing as being closer to the first resin insulating layer.

9. The semiconductor device of claim 1, wherein the conductor foil has a side surface having an inverse tapered shape with a width gradually decreasing as being closer to the first resin insulating layer.

10. The semiconductor device of claim 1, wherein:
the power semiconductor element is bonded to the conductor foil with a bonding material interposed; and
the second resin insulating layer has a greater thickness than a total of a thickness of the conductor foil and a thickness of the bonding material.

11. The semiconductor device of claim 1, wherein the second resin insulating layer includes a plurality of resin insulating layers.
